(19) United States
(12) Patent Application Publication
(10) Pub. No.: US 2024/0282572 A1
(43) Pub. Date: Aug. 22, 2024

(54) SELECTIVE DEPOSITION OF METAL OXIDE

(71) Applicant: ASM IP Holding B.V., Almere (NL)

(72) Inventors: Viraj Madhiwala, Heverlee (BE); Vincent Vandalon, Heverlee (BE); Nadadur Veeraraghavan Srinath, Leuven (BE); Eva Tois, Espoo (FI); Shaoren Deng, Ghent (BE); Daniele Chiappe, Munich (DE); Marko Tuominen, Helsinki (FI); Charles Dezelah, Helsinki (FI); YongGyu Han, Leuven (BE); Kranthi Kumar Vaidyula, Leuven (BE); Glen Wilk, Scottsdale, AZ (US); David Zanders, Leuven Flanders (BE); Aranzazu Maestre Caro, Leuven (BE)

(21) Appl. No.: 18/441,148

(22) Filed: Feb. 14, 2024

Related U.S. Application Data
(60) Provisional application No. 63/485,542, filed on Feb. 17, 2023.

(51) Int. Cl. H01L 21/02; C23C 16/04; C23C 16/40; C23C 16/455

(52) U.S. Cl. CPC H01L 21/02205; C23C 16/04; C23C 16/40; C23C 16/403; C23C 16/405; C23C 16/45527; C23C 16/45544; H01L 21/02175; H01L 21/02181; H01L 21/02189; H01L 21/02192; H01L 21/0228

(57) ABSTRACT

The disclosure relates to methods and processing assemblies selectively depositing metal oxide by cyclic vapor deposition techniques. Such methods may be used for, for example, processing semiconductor substrates. More particularly, the disclosure relates to methods and assemblies for selectively depositing a metal oxide layer. Various embodiments of the current disclosure relate to selective deposition of metal oxide layers, such as dielectric layers, etch stop layers and threshold voltage shifting layers. In particular, the disclosure relates to the deposition of metal oxide layers, such as yttrium oxide (Y₂O₃), and doped metal oxide layers, such as yttrium-doped aluminum oxide (AlYOx) by cyclic vapor deposition processes.

### CROSS-REFERENCE TO RELATED APPLICATIONS

This application claims priority to and the benefit of U.S. Provisional Application No. 63/485,542, filed Feb. 17, 2023, the entirety of which is incorporated by reference herein.

### FIELD

The present disclosure generally relates to methods and assemblies selectively depositing metal oxide by cyclic vapor deposition techniques. Such methods may be used for, for example, processing semiconductor substrates. More particularly, the disclosure relates to methods and assemblies for selectively depositing a metal oxide layer.

### BACKGROUND

Semiconductor device fabrication processes generally use advanced vapor deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Metal oxides may be used for various purposes, such as dielectric layers, etch stop layers, barriers to diffusion, and more recently, as threshold voltage shifting layers, in semiconductor devices. Selective deposition of metal oxides could allow utilizing the properties of metal oxide layers optimally, as the need for patterning and etching steps may be reduced. Thermal deposition methods may be preferred in metal oxide deposition over plasma-enhanced methods, due to better compatibility with sensitive materials. However, the quality of thermally deposited metal oxides, such as their electrical properties or etching resistance, may be lower than of metal oxides deposited using plasma.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing metal oxide layers, and in particularly selectively depositing metal oxide layers. Embodiments of the current disclosure further relate to methods of fabricating semiconductor devices, and to semiconductor processing assemblies.

Various embodiments of the current disclosure relate to selective deposition of metal oxide layers, such as dielectric layers, etch stop layers and threshold voltage shifting layers. In particular, the disclosure relates to the deposition of metal oxide layers, such as yttrium oxide (Y₂O₃), and doped metal oxide layers, such as yttrium-doped aluminum oxide (AlYOx), by cyclic vapor deposition processes. Embodiments of the current disclosure further relate to methods and processing assemblies for forming layers that allow controlling the threshold voltage of metal-oxide-semiconductor field-effect transistors (MOSFETs) and to structures formed using the methods and processing assemblies. The threshold voltage shifting layers according to the current disclosure can be used in reducing power consumption in integrated circuits, for example. Other embodiments of the current disclosure relate to methods and processing assemblies for forming layers that prevent or reduce the etching of underlying materials (etch stop layers) and to structures formed using the methods and processing assemblies.

In one aspect, a method of selectively depositing a metal oxide layer on a first surface of a semiconductor substrate relative to a second surface of the substrate is disclosed. The method comprises providing the substrate comprising the first surface and the second surface in a reaction chamber; depositing the metal oxide layer on the first surface of the substrate by a cyclic vapor deposition process; wherein the vapor deposition process comprises providing a first metal precursor into the reaction chamber in a vapor phase; and providing an oxygen precursor into the reaction chamber in a vapor phase, wherein the first metal precursor is a heteroleptic precursor comprising a group 3 metal, at least one cyclopentadienyl ligand, and at least one amidinato ligand.

In some embodiments, the first surface is a dielectric surface. In some embodiments, the dielectric surface comprises silicon. In some embodiments, the dielectric surface comprises material selected from a group consisting of SiO₂, SiN, SiC, SiOC, SiON, SiOCN, SiGe and combinations thereof.

In some embodiments, the dielectric surface comprises a metal oxide. In some embodiments, the metal oxide is selected from aluminum oxide, hafnium oxide and zirconium oxide.

In some embodiments, the second surface is a conductive surface. In some embodiments, the second surface comprises a material selected from a group consisting of a metal, amorphous carbon, metal oxide and metal nitride. In some embodiments, the second surface comprises elemental metal. In some embodiments, the metal of the second surface is selected from a group consisting of Cu, Co, Ru, W, Ti, Al, Ta and Mo.

In some embodiments, the second surface comprises passivation. In some embodiments, the passivation comprises a passivation layer on the second surface. In some embodiments, the passivation layer comprises an organic polymer. In some embodiments, the organic polymer comprises polyimide.

In some embodiments, the method comprises, before providing the first metal precursor into the reaction chamber, treating the first surface with a silylation agent and thereafter depositing an organic polymer on the second surface.

In some embodiments, the metal of the metal oxide is selected from a group consisting of scandium (Sc), yttrium (Y), lanthanum (La) and cerium (Ce). In some embodiments, the metal oxide is a scandium oxide, and the first metal precursor is a scandium precursor. In some embodiments, the metal oxide is an yttrium oxide, and the first metal precursor is an yttrium precursor. In some embodiments, the metal oxide is a lanthanum oxide, and the first metal precursor is a lanthanum precursor. In some embodiments, the metal oxide is a cerium oxide, and the first metal precursor is a cerium precursor.

In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms.

In some embodiments, the first metal precursor comprises two ethylcyclopentadienyl ligands.

In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl.

In some embodiments, the first metal precursor is selected from a group consisting of bis(isopropylcyclopentadienyl)(N,N′-diisopropylacetaminidinato)scandium (Sc(iPrCp)₂ (iPr-AMD)), bis(ethylcyclopentadienyl)(N,N′-diisopropylacetaminidinato)yttrium (Y(EtCp)₂ (iPr-AMD)), bis(isopropylcyclopentadienyl)(N,N′-diisopropylacetaminidinato)lanthanum (La(iPrCp)₂(iPr-AMD)) and bis(isopropylcyclopentadienyl)(N,N′-diisopropylacetaminidinato)cerium (Ce(iPrCp)₂(iPr-AMD)).

In some embodiments, the oxygen precursor is selected from a group consisting of molecular oxygen, ozone, hydrogen peroxide, and water.

In some embodiments, two different oxygen precursors are used in the deposition process. In some embodiments, the process according to the current disclosure has two phases. In the first phase, a first oxygen precursor is used, and in the second phase, a second oxygen precursors is used. In some embodiments, the first oxygen precursor is water. In some embodiments, the second oxygen precursor is molecular oxygen. In some embodiments, a second metal precursor is provided into the reaction chamber to deposit a metal oxide comprising two different metals.

In some embodiments, the deposited metal oxide layer has a thickness from about 0.03 nm to about 10 nm.

In some embodiments, the metal oxide layer has a wet etch rate of 0.1 nm min⁻¹ or less.

In one aspect, an etch stop layer deposited according to methods disclosed herein is disclosed.

In another aspect, a threshold voltage shifting layer deposited according to methods disclosed herein is disclosed.

In yet another aspect, a semiconductor processing assembly for selectively depositing a metal oxide layer on a substrate is disclosed. The semiconductor processing assembly comprises one or more reaction chambers constructed and arranged to hold the substrate, a precursor injector system constructed and arranged to provide a first metal precursor and an oxygen precursor into the reaction chamber in a vapor phase, wherein the semiconductor processing assembly further comprises a first metal precursor source vessel constructed and arranged to contain the first metal precursor and an oxygen source vessel constructed and arranged to contain the oxygen precursor. The semiconductor processing assembly is constructed and arranged to provide the first metal precursor and the oxygen precursor via the precursor injector system into the reaction chamber for selectively depositing metal oxide on the substrate.

In some embodiments, the semiconductor processing assembly further comprises one or more passivation source vessels, and the precursor injector system is constructed and arranged to provide one more passivation agents into the reaction chamber in a vapor phase before providing the first metal precursor into the reaction chamber.

By an etch stop layer is herein meant a layer that is resistant to the etch chemistry during via opening. An etch stop layer may have low leakage current and good TDDB reliability for fully self-aligned via scheme in the back end of line (BEOL).

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of an exemplary embodiment of a method according to the current disclosure.

FIG. 2 is a block diagram of another exemplary embodiment of a method according to the current disclosure.

FIG. 3 is a block diagram of a further exemplary embodiment of a method according to the current disclosure.

FIG. 4 is a block diagram of a yet further exemplary embodiment of a method according to the current disclosure.

FIG. 5 is a schematic presentation of exemplary embodiments of a method according to the current disclosure.

FIG. 6 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular layer, structure, device or a processing assembly, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, layers, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In one aspect, a method of selectively depositing a metal oxide layer on a first surface of a semiconductor substrate relative to the second surface of the substrate is disclosed. The method comprises providing the substrate comprising the first surface and the second surface in a reaction chamber. As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

A substrate according to the current disclosure comprises a first surface and a second surface. The first surface and the second surface have different material properties, allowing for the selective deposition of a metal oxide layer on the first surface.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

The method of depositing a metal oxide layer according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices, such as a semiconductor processing assembly. The semiconductor processing assembly may comprise one or more multi-station processing chambers. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be a single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber of the current disclosure can form part of an atomic layer deposition (ALD) assembly. The reaction chamber can form part of a chemical vapor deposition (CVD) assembly. The processing assembly may be an ALD or a CVD processing assembly. In some parts of the deposition process flow, molecular layer deposition (MLD) may be employed. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

### Cyclic Vapor Deposition

When the substrate is provided in the reaction chamber, a metal oxide layer is deposited on the first surface of the substrate by a cyclic vapor deposition process. Cyclic deposition in the current disclosure refers to vapor deposition processes in which deposition cycles, typically a plurality of consecutive deposition cycles, are conducted in a process chamber.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first metal precursor into the reaction chamber. In some embodiments, the cyclic deposition process comprises purging the reaction chamber after providing an oxygen precursor into the reaction chamber. In some embodiments, the cyclic deposition process comprises purging the reaction chamber after providing a second metal precursor into the reaction chamber. In some embodiments, the cyclic deposition process comprises purging the reaction chamber after providing a first metal precursor into the reaction chamber, after providing an oxygen precursor into the reaction chamber and after providing a second metal precursor into the reaction. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

In some embodiments, the cyclic method according to the current disclosure comprises providing a first metal precursor and an oxygen precursor into the reaction chamber alternately and sequentially. Such a configuration for providing the two precursors (i.e., first metal precursor pulse and oxygen precursor pulse, respectively), may be beneficial in view of controlled layer growth, layer uniformity and/or conformality. The second metal precursor may be also provided alternately and sequentially relative to the first metal precursor and/or the oxygen precursor.

In some embodiments, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. A single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. The process may comprise one or more cyclic phases. In some embodiments, the process comprises or one or more acyclic (i.e. continuous) phases. An example of a continuous phase could be a pre-treatment with a single reactant. In some embodiments, the deposition process comprises the continuous flow of at least one precursor. In some embodiments, one or more of the precursors are provided in the reaction chamber continuously.

In some embodiments, at least one of first metal precursor, oxygen precursor and second metal precursor is provided into the reaction chamber in pulses. In some embodiments, the first metal precursor is supplied in pulses and the oxygen precursor is supplied in pulses, and the reaction chamber is purged between consecutive pulses of first metal precursor and oxygen precursor. In some embodiments, the second metal precursor is supplied in pulses and the oxygen precursor is supplied in pulses, and the reaction chamber is purged between consecutive pulses of second metal precursor and oxygen precursor. In some embodiments, the first metal precursor is supplied in pulses and the second metal precursor is supplied in pulses, and the reaction chamber is purged between consecutive pulses of first metal precursor and second metal precursor. A duration of providing first metal precursor and/or a second metal precursor into the reaction chamber (i.e. first metal precursor pulse time and second metal precursor pulse time, respectively) may be, for example, from about 0.1 s to about 60 s, for example from about 0.1 s to about 5 s, or from about 1 s to about 20 s, or from about 1 s to about 8 s, or from about 0.5 s to about 10 s, or from about 5 s to about 15 s, or from about 10 s to about 30 s, or from about 10 s to about 60 s, or from about 20 s to about 60 s. The duration of first metal precursor or a second metal precursor pulse may be, for example about 0.3 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, first metal precursor or second metal precursor pulse time may be at least 1 second, or at least 3 seconds. In some embodiments, first metal precursor or second metal precursor pulse time may be at most 2 seconds, or at most 5 seconds or at most 10 seconds, or at most 30 seconds.

A duration of providing oxygen precursor into the reaction chamber (i.e. oxygen precursor pulse time) may be, for example, from about 0.05 s to about 60 s, for example from about 0.05 s to about 5 s, or from about 0.1 s to about 20 s, or from about 0.2 s to about 8 s, or from about 0.5 s to about 10 s, or from about 5 s to about 15 s, or from about 10 s to about 30 s, or from about 10 s to about 30 s, or from about 20 s to about 60 s. The duration of oxygen precursor pulse may be, for example about 0.15 s, 0.2 s, 0.3 s, 0.4 s, 0.5 s, 1 s, 1.5 s, 2 s, 2.5 s, 3 s, 5 s, 7 s, 10 s, 12 s, 15 s, 25 s, 30 s, 40 s, 50 s or 60 s. In some embodiments, oxygen precursor pulse time may be at least 0.25 seconds, or at least 0.5 seconds. In some embodiments, oxygen precursor pulse time may be at most 2 seconds, or at most 5 seconds or at most 10 seconds, or at most 30 seconds.

In some embodiments, one metal precursor and two different oxygen precursors are used. The process may be initiated by using a first oxygen precursor, and a first metal precursors for a predetermined number of cycles, and the first metal precursor and a second oxygen precursor for a second number of predetermined cycles. Such a two-phase process may be described, as a(M+O1)+b(M+O2), wherein M denotes a first metal precursor pulse, O1 a first oxygen precursor pulse, O2 a second oxygen precursor pulse, and a and b the number of times a deposition cycle using each of the precursor combinations is performed. The repetitions for each precursor combination can be independently selected. In some embodiments, each of a and be is independently performed from 1 to about 200 times. For example, each of a and b can be performed from 1 to about 200 times, such as from 1 to about 150 times, from 1 to about 100 times, from 1 to about 80 times, from 1 to about 50 times, from 1 to about 20 times or from 1 to about 10 times or from about 10 times to about 20 times, or from about 10 times to about 30 times, such as one time or 2, 3, 4, 5, 6, 7, 8, 9 or 10 cycles.

In some embodiments, the first oxygen precursor (O1 in the formula above) is water. In some embodiments, the second oxygen precursor (O2 in the formula above) is molecular oxygen. The combination of oxygen precursors, in which the first oxygen precursor is water, and the second oxygen precursor is molecular oxygen, may be particularly advantageous when the metal oxide according to the current disclosure is deposited on silicon-containing surface, such as native or deposited silicon oxide. Without limiting the current disclosure to any specific theory, using water in the beginning of the deposition process may lead to formation of metal silicide (such as yttrium silicide) in the interface of the silicon-containing layer and the deposited metal oxide layer, which may be beneficial for the final device properties, particularly in applications in which the metal oxide is used as a dipole layer. Further layer uniformity may be improved, and growth delay reduced. In some embodiments, particularly when yttrium oxide is deposited on metal oxide, such as yttrium oxide, molecular oxygen is used throughout the process.

The pulse times for first metal precursor, for second metal precursor and for oxygen precursor vary independently according to the process in question. The selection of an appropriate pulse time may depend on the substrate topology. For higher aspect ratio structures, longer pulse times may be needed to obtain sufficient surface saturation in different areas of a high aspect ratio structure. Also the selected precursor chemistries may influence suitable pulsing times. For process optimization purposes, shorter pulse times might be preferred as long as appropriate layer properties can be achieved. In some embodiments, first metal precursor pulse time is longer than second metal precursor pulse time. In some embodiments, second metal precursor pulse time is longer than first metal precursor pulse time. In some embodiments, first metal precursor pulse time is the same as second metal precursor pulse time. In some embodiments, first metal precursor pulse time is longer than oxygen precursor pulse time. In some embodiments, oxygen precursor pulse time is longer than first metal precursor pulse time. In some embodiments, first metal precursor pulse time is the same as oxygen precursor pulse time. In some embodiments, second metal precursor pulse time is longer than oxygen precursor pulse time. In some embodiments, oxygen precursor pulse time is longer than second metal precursor pulse time. In some embodiments, second metal precursor pulse time is the same as oxygen precursor pulse time.

In some embodiments, providing a first metal precursor and/or a second metal precursor into the reaction chamber comprises pulsing the first metal precursor and the second metal precursor over a substrate. In certain embodiments, pulse times in the range of several minutes may be used for the first metal precursor and/or the second metal precursor. In some embodiments, first metal precursor may be pulsed more than one time, for example two, three or four times, before a second metal precursor or an oxygen precursor is pulsed to the reaction chamber. Similarly, there may be more than one pulse, such as two, three or four pulses, of a second metal precursor or oxygen precursor before first metal precursor is pulsed (i.e., provided) into the reaction chamber.

In the methods according to the current disclosure, the vapor deposition process comprises providing a first metal precursor into the reaction chamber in a vapor phase, providing an oxygen precursor into the reaction chamber in a vapor phase. In some embodiments, a deposition cycle comprises providing a second metal precursor into the reaction chamber, As described above, the process is a cyclic deposition process, so providing (i.e., pulsing) the precursors into the reaction chamber is repeated. The pulses may be repeated as desired, depending on, for example, the growth rate of the metal oxide layer, and on the intended thickness of the metal oxide layer. In some embodiments, the growth rate of the metal oxide layer is from about 0.01 nm per cycle to about 0.5 nm per cycle. In some embodiments, the growth rate of the metal oxide layer is from about 0.01 nm per cycle to about 0.05 nm per cycle, such as about 0.02 nm per cycle or about 0.03 nm per cycle. In some embodiments, the growth rate of the metal oxide layer is from about 0.01 nm per cycle to about 0.1 nm per cycle, such as about 0.07 nm per cycle or about 0.09 nm per cycle. In some embodiments, the growth rate of the metal oxide layer is from about 0.05 nm per cycle to about 0.3 nm per cycle, such as about 0.15 nm per cycle or about 0.2 nm per cycle or about 0.25 nm per cycle. In some embodiments, the growth rate of the metal oxide layer is from about 0.1 nm per cycle to about 0.5 nm per cycle, such as about 0.35 nm per cycle or about 0.4 nm per cycle or about 0.45 nm per cycle.

For example, in some embodiments, yttrium oxide can be deposited using Y(EtCp)₂ (iPr-AMD) as the first metal precursor and molecular oxygen (O₂) as the oxygen precursor. The process may be performed at a temperature of about 300° C., the yttrium oxide having a growth rate of less than 0.1 nm/cycle, such as less than 0.05 nm/cycle. A process in which molecular oxygen is used as an oxygen precursor may further have the feature of a delay in observable growth initiation. Such delay may be, for example, at least about 10 cycles, or at least about 15 cycles on silicon-containing surface, such as silicon containing a native oxide surface. For comparison, using water as an oxygen precursor under the same growth conditions, there may be no growth delay, and the growth rate of yttrium oxide may be higher than 0.1 nm/cycle. The growth rate of yttrium oxide may differ on different surfaces and it may be higher on, for example, metal oxide surfaces, such as on an yttrium oxide surface, where the growth rate may be from about 0.05 to about 0.09 nm/cycle. An advantage of using water as an oxygen precursor may be an improvement of thickness uniformity of the layers compared to alternative methods. Especially when very thin layers of under 5 nm are targeted, the uniform deposition over the targeted deposition area is vital for the correct device functioning. The metal oxide layer thickness may be selected according to the application in question. In some embodiments, the deposited metal oxide layer has a thickness from about 0.03 nm to about 10 nm. Thus, depending on the growth rate of the metal oxide layer, the deposition cycle may be performed from about 2 to about 800 times. For example, a deposition cycle may be performed about 2, 3, 5, 7, 10, 13, 15, 20, 40, 50, 100, 200, 300, 500 or 600 times.

In some embodiments, the metal oxide layer according to the current disclosure is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr. For example, the metal oxide layer may be deposited at a pressure of about 1 Torr, about 3 Torr, about 6 Torr, about 8 Torr, about 9 Torr, about 12 Torr or about 18 Torr.

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes. For example, one challenge has been finding suitable dielectric stacks that form an insulating barrier between a gate and a channel of a field effect transistor, while keeping the number of processing steps economic and feasible for allowing reliable device manufacture. One particular problem in this regard is the deposition of layers controlling the threshold voltage of field effect transistors. Thus, in one aspect, a threshold voltage shifting layer deposited according to methods disclosed herein is disclosed. Thus, in some embodiments, the metal oxide layer is a threshold voltage shifting layer. The term “threshold voltage” as used herein refers to a minimum gate voltage required to create a conductive path between the source and drain terminals of a field effect transistor. The term “threshold voltage shifting layer” as used herein refers to a layer which is useful for controlling the threshold voltage of a metal oxide field effect transistor. Thus, it refers to a layer which can be used in the gate stack of a field effect transistor, and which can change the threshold voltage of that field effect transistor. It may be equivalent to similar terms such as “threshold voltage tuning layer”, “dipole layer”, or “threshold voltage controlling layer”.

In such embodiments, layers of, for example, about 1 nm or less in thickness, may be desired. Correspondingly a deposition cycle may be performed from about 2 times to about 100 or 150 times, such as about 2, 3, 5, 7, 10, 13, 15, 20, 40, 50, 75 or 120 times.

The present methods and devices for selectively depositing a threshold voltage shifting layer are particularly useful for controlling the threshold voltage of n-channel field effect transistors, such as n-channel metal-oxide semiconductor field effect transistors, and such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, and such as p-channel gate-all-around metal oxide semiconductor field effect transistors. In particular, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices are particularly useful for decreasing the gate voltage at which a conductive channel is produced between the source and drain of a p-MOSFET. The p-MOSFET may, for example, be comprised in a CMOS-based integrated circuit. In other words, the present methods and devices are particularly useful for increasing the voltage at which an n-MOSFET switches from an off-state to an on-state, and for decreasing the voltage at which a p-MOSFET switches from an off-state to an on-state. Similarly, the present methods and devices are particularly useful for increasing the flat band voltage of n-MOSFETS, and for decreasing the flat band voltage of p-MOSFETS. In addition, the present methods and devices are particularly useful for the manufacture of n-MOSFETS and p-MOSFETS with a gate-all-around architecture. Additionally or alternatively, the present methods and devices may be of particular use in the context of systems-on-a-chip. Advantageously, the presently disclosed methods allow depositing threshold shifting layers contributing only minimally to the equivalent oxide thickness of the gate dielectric stack while simultaneously offering a low growth rate and providing a significant positive threshold voltage shift. Advantageously, the presently disclosed methods allow depositing threshold shifting layers having a low impurity content, such as a carbon content of less than 25 at-%.

The presently described methods and devices are useful for controlling the threshold voltage of field effect transistors. In some embodiments, the present methods and devices are particularly useful for controlling the threshold voltage of n-channel field effect transistors, such as n-channel metal-oxide semiconductor field effect transistors, and such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In particular, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices are particularly useful for decreasing the gate voltage at which a conductive channel is produced between the source and drain of a p-MOSFET. The p-MOSFET may, for example, be comprised in a CMOS-based integrated circuit.

In some embodiments, the metal oxide layer is an etch stop layer. The term “etch stop layer” as used herein refers to a layer that has a lower etch rate than another material on the same substrate in an etching process used in a process for manufacturing a semiconductor device. An etch stop layer is used to protect an underlying material from etching. In some embodiments, an etch stop layer is substantially note etched under the etching conditions it is used. An etch stop layer may not have the desired properties for the semiconductor device, so it may be removed after the etching is complete. In some cases, for example, when the etch stop layer is sufficiently thin, or does not otherwise adversely affect the semiconductor device, it may remain in the final structure. An etch stop layer may have a thickness of from about 0.5 nm to about 10 nm, such as about 1 nm, about 2 nm, about 3 nm or about 4 nm, about 5 nm or about 7 nm. Correspondingly, to achieve the desired thickness of an etch stop layer, a deposition cycle may be performed from about 2 times to about 500 or about 600 times, such as about 3, 5, 10, 15, 25, 50, 75, 100, 150, 200, 250, 300, 400, 450 or 550 times. As a metal oxide etch stop layer may be very etch resistant, using, for example an yttrium oxide layer may have advantages, as it can be kept very thin, such as under 2 nm or under 1 nm, or under 0.5 nm.

As an example, yttrium oxide (Y₂O₃)-based etch stop layers may be used as hard masks in patterning of structures on semiconductor substrates. Metal oxide, such as yttrium oxide, hard masks demonstrate a much higher etch resistance than carbon-based ones, preventing, for example, the “corner rounding” phenomenon during extended etch processes. By depositing very thin (from about 1 Å to about 10 Å) yttrium oxide layers, the main drawbacks, such as difficulty of removal and effects on device stack performance if not removed, associated with thicker yttrium oxide etch stop layers can be mitigated or omitted. In addition to selective deposition, the yttrium oxide-based hard mask can be used in a non-selective fashion as it can be patterned and removed effectively with chlorine-based wet etch, while it is not etched by HF. Thus, in some embodiments, the etch stop layer described herein may be deposited on a substrate comprising one or more surfaces, substantially without selectivity. In other words, in some embodiments, an etch-stop layer according to the current disclosure may be non-selectively deposited. This may be achieved by selecting a substrate, on which the deposition surfaces are inherently non-selective to the current chemistry, and omitting any passivation disclosed herein.

However, yttrium oxide can also be deposited with excellent selectivity by using, heteroleptic precursor comprising yttrium and, at least one cyclopentadienyl ligand and at least one amidinato ligand. Yttrium oxide deposition is selective against surfaces comprising an organic passivation, such as polyimide-comprising passivation. Also, yttrium oxide may be deposited on high k materials, such as on HfO₂ relative to a silylated silicon-containing surface, such as silicon oxide. A selective workflow could eliminate the process steps including the wet-etch to pattern the hard mask, which may be beneficial in many applications. In some embodiments, a substrate comprising a hafnium oxide—comprising first surface may be treated with hydrogen plasma prior to the deposition. In some embodiments, the substrate is treated with hydrogen plasma for about 5 seconds, about 10 seconds, about 20 seconds or about 30 seconds. This may improve the growth rate of the metal oxide on the substrate surface.

An etch stop layer may be removed after the etching process is completed. However, if the etch stop layer is thin enough, there may not be a need to remove it. This may be advantageous in cases where a very resistant etch stop layer is required, and its removal could be challenging. Alternatively or in addition, if the etch stop layer may remain in the completed structure, the process may become simpler, as the removal step for the etch stop layer may be omitted.

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD. For example, in some embodiments, the metal oxide layer deposition may be performed by PEALD or PECVD.

### Selectivity

The current disclosure relates to a selective deposition process. Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In some embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition is inherent, and no additional processing steps over those conveniently performed on a substrate are necessary. However, in some embodiments, the second surface may be passivated before depositing a metal oxide layer on the first surface. Selectivity may be inherent to a certain thickness of deposited material, and be lost in case deposition is continued beyond a process-specific threshold. Thus, it may be possible to deposit a metal oxide layer of, for example, about 0.1 nm, about 0.5 nm, about 1 nm, about 2 nm, about 3 nm, about 5 nm or about 6 nm before selectivity is lost. If thicker material layers are desired, the contrast between the first surface and the second surface may be enhanced though passivating the second surface. Alternatively or in addition, intermittent etch-back phase using, for example plasma, such as hydrogen plasma, may be used to keep the process sufficiently selective. In some embodiments, the second surface comprises passivation. In some embodiments, the passivation comprises a passivation layer on the second surface. In some embodiments, the passivation layer comprises an organic polymer. In some embodiments, the organic polymer comprises polyimide. In some embodiments, the passivation comprises a silylation of the second surface.

In some embodiments, the first surface is a dielectric surface. In some embodiments, the first surface is a low-k surface. By a low k surface is herein meant a surface having at most a similar k value as silicon oxide. In some embodiments, the first surface comprises an oxide. In some embodiments, the first surface comprises a nitride. In some embodiments, the first surface comprises silicon. In some embodiments, the first surface comprises silicon-based dielectric material. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride. In some embodiments, the first dielectric surface comprises material selected from a group consisting of SiO₂, SiN, SiC, SiOC, SiON, SiOCN, SiGe and combinations thereof.

In some embodiments, the substrate comprises a first dielectric surface and a second metal or metallic surface. In some embodiments, the substrate comprises a first metal oxide surface. In some embodiments, the first surface may comprise-OH groups. In some embodiments, the first surface may be a SiO₂-based surface. In some embodiments, the first surface may comprise Si—O bonds. In some embodiments, the first surface may comprise a SiO₂-based low-k material. In some embodiments, the first surface may comprise more than about 30%, or more than about 50% of SiO₂. In certain embodiments the first surface may comprise a silicon dioxide surface

In some embodiments, the first surface is a SiO₂ surface and the second surface is a metal surface. In some embodiments, the first surface is a SiN surface, and the second surface is a metal surface, such as an elemental metal surface. In some embodiments, the first surface is a SiOC surface, and the second surface is a metal surface. In some embodiments, the first surface is a SiON surface, and the second surface is a metal surface. In some embodiments, the first surface is a SiOCN surface, and the second surface is a metal surface. The second metal surface may be, for example, a copper surface, a ruthenium surface, a tungsten surface, a cobalt surface.

In some embodiments the dielectric material of the first surface comprises a metal oxide. Thus, in some embodiments, a metal oxide layer is selectively deposited on a first metal oxide surface relative to a second surface. In some embodiments, the first surface comprises aluminum oxide. In some embodiments, the first surface is a high-k surface, such as hafnium oxide-comprising surface, a lanthanum oxide-comprising surface.

In some embodiments, a metal oxide layer is selectively deposited on a first surface comprising a metal oxide relative to another surface. A metal oxide surface may be, for example a tungsten oxide (WOx) surface, hafnium oxide (HfOx) surface, titanium oxide (TiOx) surface, aluminum oxide (AlOx) surface or zirconium oxide (ZrOx) surface. In some embodiments, a metal oxide surface is an oxidized surface of a metallic material. In some embodiments, a metal oxide surface is created by oxidizing at least the surface of a metallic material using oxygen compound, such as compounds comprising O3, H₂O, H₂O₂, O₂, oxygen atoms, plasma or radicals or mixtures thereof. In some embodiments, a metal oxide surface is a native oxide formed on a metallic material.

In some embodiments, a metal oxide layer, is selectively deposited on a first dielectric surface of a substrate relative to a second conductive (e.g., metal or metallic) surface of the substrate. In some embodiments, the first surface comprises hydroxyl (—OH) groups. In some embodiments, the first surface may additionally comprise hydrogen (—H) terminations, such as an HF dipped Si or HF dipped Ge surface. In such embodiments, the surface of interest will be considered to comprise both the —H terminations and the material beneath the —H terminations. In some embodiments the first surface and the second surface are adjacent to each other.

In some embodiments, a metal oxide layer is selectively deposited on a first dielectric surface of a substrate relative to a second, different dielectric surface. In some such embodiments, the dielectrics have different compositions. In some embodiments, the first surface comprises a metal oxide. In some embodiments, the metal oxide is selected from aluminum oxide, hafnium oxide and zirconium oxide. In some embodiments, the first surface comprises a high k material. In some embodiments, the high k material is selected from a group consisting of hafnium oxide, zirconium oxide and combinations thereof. In some embodiments, the first surface is a hafnium oxide surface. In some embodiments, the first surface is a zirconium oxide surface. In some embodiments, the first surface is a hafnium zirconium oxide surface. In some embodiments, the first surface is a hafnium oxide surface and the second surface is a silicon-containing surface. In some embodiments, the first surface is a zirconium oxide surface and the second surface is a silicon-containing surface. In some embodiments, the first surface is a hafnium zirconium oxide surface and the second surface is a silicon-containing surface.

In some embodiments, passivation, such as silylation, is used to improve contrast between two dielectric surfaces before depositing a metal oxide layer on the first dielectric surface. In some embodiments, the first surface is a high k surface, and the second surface is a passivated low k surface. In some embodiments, the first surface is a hafnium oxide surface and the second surface is a silylated silicon-containing surface. In some embodiments, the first surface is a zirconium oxide surface and the second surface is a silylated silicon-containing surface. In some embodiments, the first surface is hafnium zirconium oxide surface and the second surface is a silylated silicon-containing surface. The silicon-containing second surface, such as SiO₂, SiN, SiC, SiON or SiOC surface, may be selectively silylated relative to the first surface by a silylating agent. In some embodiments, the silicon-containing second surface is silylated by exposure to a silylation agent, such as an alkylsilane, for example allyltrimethylsilane (TMS-A), halosilane, for example chlorotrimethylsilane (TMS-Cl) or octadecyltrichlorosilane (ODTCS), an imidazole, for example N-(trimenthylsilyl)imidazole (TMS-Im), a silazane, for example hexamethyldisilazane (HMDS), or a silylamine, for example N-(trimethylsilyl)dimethylamine (TMSDMA). Silylation may passivate the second surface against the deposition of the metal oxide layer on the second surface.

In some embodiments, the method comprises, before providing the first metal precursor into the reaction chamber, passivating the first surface with a silylation agent and thereafter depositing an organic polymer on the second surface. For example, the first surface may be a dielectric surface comprising silicon, and the second surface may be a metal or a metallic surface. The first dielectric surface may be passivated with a silylating agent, allowing the second metal or metallic surface to be passivated by an organic polymer-comprising passivation, such as polyimide-comprising passivation layer. The metal oxide layer according to the current disclosure may be deposited on the first surface after the initial silylation passivation has been removed.

Thus, in some embodiments, the second surface comprises a passivated metal surface. That is, in some embodiments, the second surface may comprise a metal surface comprising a passivation agent, for example an organic passivation layer such as a polyimide-comprising passivation layer or a self-assembled monolayer. In some embodiments, the passivation layer remains on the second surface over at least two, such as at least about 10, about 20, about 50, about 100 or about 150 deposition cycles of the metal oxide. In other words, a passivation layer, such as polyimide-comprising layer, is used that is able to withstand the deposition conditions over an extended period of time.

In some embodiments, a metal oxide layer is selectively deposited on a first dielectric surface of a substrate relative to a second metal or metallic surface of the substrate. In some embodiments, the second surface comprises a metal oxide, elemental metal, or metallic surface. In some embodiments, the second metal or metallic surface comprises a passivation layer comprising polyamic acid, polyimide, or other polymeric material.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity. Selective deposition processes taught herein can deposit on dielectric surfaces with minimal deposition on such adjacent non-conductive metal or metallic surfaces.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination of conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the second surface is a conductive surface. In some embodiments, the second surface comprises a material selected from a group consisting of a metal, amorphous carbon, metal oxide and metal nitride. In some embodiments, the second surface comprises elemental metal. In some embodiments, the metal of the second surface is selected from a group consisting of Cu, Co, Ru, W, Ti, Al, Ta and Mo.

### Metal Precursors

In the current disclosure, the metal oxide layer is deposited using a first metal precursor and an oxygen precursor. The first metal precursor according to the current disclosure is a heteroleptic precursor comprising a group 3 metal, at least one cyclopentadienyl ligand and at least one amidinato ligand. In the current disclosure, group 3 element means scandium (Sc), yttrium (Y) and lanthanides. In some embodiments, the metal of the metal oxide is selected from a group consisting of scandium (Sc), yttrium (Y), lanthanum (La) and cerium (Ce).

In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms. In some embodiments, a cyclopentenyl group comprises at least one alkyl substituent, wherein the alkyl substituent is selected from C1 to C5 alkyls. In some embodiments, the alkyl substituent is selected from a group consisting of methyl, ethyl and linear or branched alkyl group comprising three, four or five carbon atoms. In some embodiments, the alkyl substituent is selected from a group consisting of methyl, ethyl, n-propyl, isopropyl, n-butyl, isobutyl, sec-butyl, tert-butyl, n-pentyl, 1,1-dimethylpropyl, 3-methylbutyl, 1-methylbutyl, 2,2-dimethylpropyl, 1-ethylpropyl, 1,2-dimethylpropyl and 2-methylbutyl. In some embodiments, the first metal precursor comprises two methylcyclopentadienyl ligands. In some embodiments, the first metal precursor comprises two ethylcyclopentadienyl ligands. In some embodiments, the first metal precursor comprises two n-propylcyclopentadienyl ligands. In some embodiments, the first metal precursor comprises two isopropylcyclopentadienyl ligands.

In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl. In some embodiments, the acetamidinato group comprises two identical alkyl groups.

The following abbreviations are used in the current disclosure: Me stands for methyl; Et stands for ethyl; Pr stands for propyl; iPr stands for isopropyl; nPr stands for n-propyl; Bu stands for butyl; tBu stands for tert-butyl, sBu stands for sec-butyl; tPn stands for tert-pentyl; Cp stands for cyclopentadienyl; AMD stands for acetamidinato, mmp stands for 1-methoxy-2-methyl-propanolato; acac stands for acetylacetonato; FMD stands for formamidinate; dpguan stands for N,N′-diisopropyl-2-dimethylamidoguanidinato; and triaz stands for triazenide.

In some embodiments, the metal oxide layer comprises scandium, and the first metal precursor is a scandium precursor. In some embodiments, the metal oxide is a scandium oxide, and the first metal precursor is a scandium precursor. In some embodiments, the scandium precursor comprises at least one cyclopentadienyl ligand or an alkyl-substituted variant thereof, and at least one amidinato ligand. In some embodiments, the scandium precursor comprises at least one cyclopentadienyl ligand or an alkyl-substituted variant thereof and at least one alkyl acetamidinato ligand. In some embodiments, the scandium precursor comprises a heteroleptic scandium precursor, such as a precursor comprising at least one alkyl-substituted cyclopentadienyl ligand and at least one alkyl acetamidinato ligand. In some embodiments, the scandium precursor is bis(isopropylcyclopentadienyl)(N,N′-diisopropylacetaminidinato)scandium (Sc(iPrCp)₂ (iPr-AMD)).

The oxidation state of the metal in the first metal precursor may be higher than 0. The oxidation state of the metal in the first metal precursor may be 3.

In some embodiments, the metal oxide layer comprises yttrium, and the first metal precursor is an yttrium precursor. In some embodiments, the metal oxide is an yttrium oxide, and the first metal precursor is an yttrium precursor. In some embodiments, the yttrium precursor comprises at least one cyclopentadienyl ligand or an alkyl-substituted variant thereof and at least one amidinato ligand. In some embodiments, the yttrium precursor comprises at least one cyclopentadienyl ligand or an alkyl-substituted variant thereof and at least one alkyl acetamidinato ligand. In some embodiments, the yttrium precursor comprises at least one cyclopentadienyl ligand or an alkyl-substituted variant thereof and at least one amidinato ligand. In some embodiments, the yttrium precursor comprises a heteroleptic yttrium precursor, such as a precursor comprising at least one alkyl-substituted cyclopentadienyl ligand and at least one alkyl acetamidinato ligand. In some embodiments, the yttrium precursor is bis(ethylcyclopentadienyl)(N,N′-diisopropylacetaminidinato)yttrium (Y(EtCp)₂ (iPr-AMD)).

In some embodiments, the metal oxide layer comprises lanthanum, and the first metal precursor is a lanthanum precursor. In some embodiments, the metal oxide is a lanthanum oxide, and the first metal precursor is a lanthanum precursor. In some embodiments, the lanthanum precursor comprises at least one cyclopentadienyl ligand or an alkyl-substituted variant thereof. In some embodiments, the lanthanum precursor comprises at least one amidinato ligand. In some embodiments, the lanthanum precursor comprises at least one cyclopentadienyl ligand or an alkyl-substituted variant thereof and at least one alkyl acetamidinato ligand. In some embodiments, the lanthanum precursor comprises a heteroleptic lanthanum precursor, such as a precursor comprising at least one alkyl-substituted cyclopentadienyl ligand and at least one alkyl acetamidinato ligand. In some embodiments, the lanthanum precursor comprises bis(isopropylcyclopentadienyl)(N,N′-diisopropylacetaminidinato)lanthanum (La(iPrCp)₂ (iPr-AMD)).

In some embodiments, the metal oxide layer comprises cerium, and the first metal precursor is a cerium precursor. In some embodiments, the metal oxide is a cerium oxide, and the first metal precursor is a cerium precursor. In some embodiments, the cerium precursor comprises at least one cyclopentadienyl ligand or an alkyl-substituted variant thereof. In some embodiments, the cerium precursor comprises at least one amidinato ligand. In some embodiments, the cerium precursor comprises at least one cyclopentadienyl ligand or an alkyl-substituted variant thereof and at least one alkyl acetamidinato ligand. In some embodiments, the cerium precursor comprises a heteroleptic cerium precursor, such as a precursor comprising at least one alkyl-substituted cyclopentadienyl ligand and at least one alkyl acetamidinato ligand. In some embodiments, the cerium precursor comprises bis(isopropylcyclopentadienyl)(N,N′-diisopropylacetaminidinato)cerium (Ce(iPrCp)₂ (iPr-AMD)).

In some embodiments, the first metal precursor according to the current disclosure may be presented by the formula M(RCp)ₓ[R′N(CR″)NR′″]_{y}, wherein M is selected from Sc, Y, La, Ce and other rare earth elements, R is H, Me, Et, iPr, tBu, R′ is Et, iPr, tBu, tPn, R″ is H, Me, Et, Pr, Bu, R′″ is Et, iPr, tBu, tPn and x+y=3, wherein x and y are both integers greater than zero. This example would be for compounds comprising both Cp and amidinate type ligands.

In some embodiments, a second metal precursor is provided into the reaction chamber. The second metal precursor may contain the same metal as the first metal precursor or a different metal. In some embodiments, in which the second metal precursor comprises a different metal than the first metal precursor, the metal oxide layer comprises two metals. The molar ratio of the first metal to second metal in a metal oxide layer comprising two metals may vary from 1:50 to 50:1. In the most extreme embodiments, the metal oxide layer comprises mostly the first metal or the second metal, and the other one is used as a dopant. In some embodiments, the molar ratio of the first metal to second metal in a metal oxide layer comprising two metals varies from about 1:20 to about 20:1 or from about 1:10 to about 10:1 or from about 1:5 to about 5:1. In some embodiments, the molar ratio of the first metal to second metal in a metal oxide layer comprising two metals varies from about 1:3 to about 3:1 or from about 1:2 to about 2:1. In some embodiments, the molar ratio of the first metal to second metal in a metal oxide layer comprising two metals is about 1:2, about 2:1, about 3:2, about 2:3 or about 1:1.

In some embodiments, the second metal is a transition metal, and the second metal precursor is a transition metal precursor. In some embodiments, the second metal is a post-transition metal, and the second metal precursor is a post-transition metal precursor. In some embodiments, the second metal is a group 13 metal, and the second metal precursor is a group 13 metal precursor. In some embodiments, the group 13 metal is selected from a group consisting of aluminum, gallium and indium. In some embodiments, the group 13 metal is aluminum, and the second metal precursor is an aluminum precursor. In some embodiments, the group 13 metal is gallium, and the second metal precursor is a gallium precursor. In some embodiments, the group 13 metal is indium, and the second metal precursor is an indium precursor. Examples of aluminum precursors include but are not limited to AlMe₃, AlEt₃, Al(OEt)₃, Al(OnPr)₃, Al(OiPr)₃, Al(OsBu)₃, Al(iPrAMD)Et₂, Al(mmp)₃, Al(NMe₂)₃, Al(NEt₂)₃, AlCl₃, AlMe₂Cl, AlMe₂OiPr, Al(NiPr₂)₃ and Al(NiPr₂)₂(C₃H₆NMe₂). Examples of gallium precursors include but are not limited to Ga(acac)₃, Ga(CpMe₅), Ga₂(NMe₂)₆ and GaMe₂ (OiPr). Examples of gallium precursors include but are not limited to In(acac)₃, In(dpguan)₃, In(EtCp), In(iPrAMD)₃, In(iPrFMD)₃, In(N(SiMe₃)₂)Et₂, In(PrNMe₂)Me₂, In(triaz)₃, InCl₃, InCp, InMe₂(edpa), InMe₃, InMe₃(MeO(CH₂)₂NHtBu).

The metal oxide layer according to the current disclosure is deposited by providing an oxygen precursor into the reaction chamber. In some embodiments, the oxygen precursor is selected from a group consisting of ozone (O₃), molecular oxygen (O₂), oxygen atoms (O), an oxygen plasma, oxygen ions, oxygen radicals, oxygen excited species, water (H₂O), and hydrogen peroxide (H₂O₂). In some embodiments, the oxygen precursor is molecular oxygen (O₂). In some embodiments, the oxygen precursor is ozone. In some embodiments, the oxygen precursor is hydrogen peroxide. In some embodiments, the oxygen precursor is water. Without limiting the current disclosure to any specific theory, the oxygen precursor provided into the reaction chamber may react with the first and/or second metal precursor, or a derivative thereof, chemisorbed on the first surface of the substrate to form metal oxide on the first surface.

In accordance with some exemplary embodiments, a structure is formed using methods as described herein. The structure can include a substrate and a metal oxide layer, such as a threshold voltage shifting layer or an etch stop layer, formed overlying a surface of the substrate. Exemplary structures can further include one or more additional layers, such as an additional metal or conducting layer overlying the metal oxide layers and/or one or more insulating or dielectric layers underneath the metal oxide layer. The structure can be or form part of a CMOS structure, such as one or more of a PMOS and NMOS structure, or other device structure.

In accordance with yet additional embodiments of the disclosure, a device or portion thereof can be formed using methods and/or structures as described herein. The device can be or form part of, for example, a CMOS device.

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative etch rates of different materials indicated in the drawings may deviate from the experimental results, the specifics of which may vary according to process conditions. The layers, structures, devices and processing assemblies depicted in the drawings may contain additional elements and details, which may be omitted for clarity.

For the sake of brevity, conventional manufacturing, connection, preparation, and other functional aspects of the methods, layers, structures, devices and processing assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

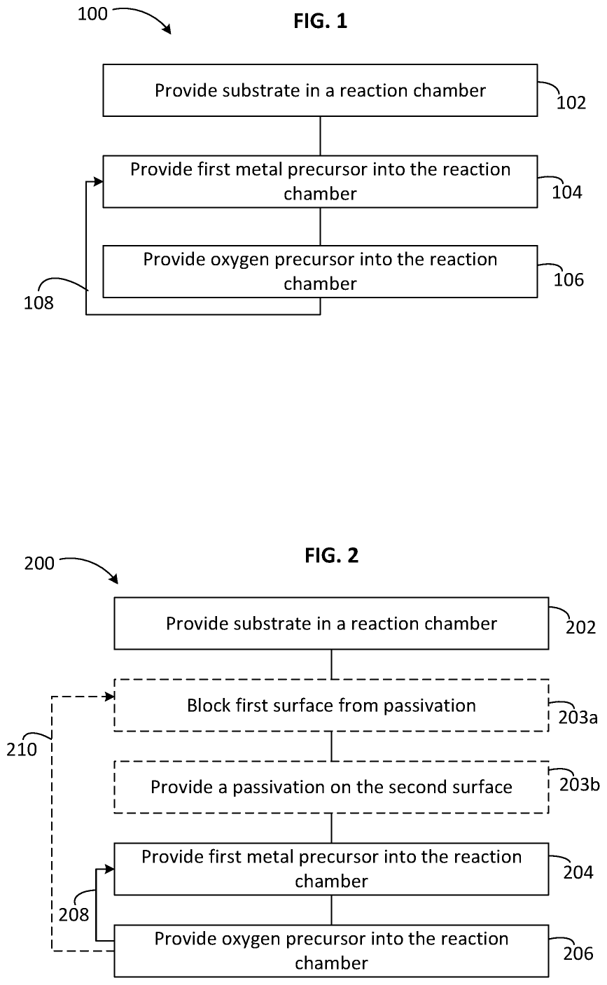

FIG. 1 is a block diagram of an exemplary embodiment of a method 100 according to the current disclosure. First, a substrate is provided in a reaction chamber at stage 102. The substrate comprises a first surface and a second surface as described in the current disclosure. For example, the first surface may be a dielectric surface, and the second surface may be a metal or a metallic surface. In some embodiments, the first surface is a high k surface, and the second surface is a silicon-containing dielectric surface, such as a low k surface. The substrate may be heated at stage 102 prior to providing a first metal precursor into the reaction chamber.

At stage 104, a first metal precursor is provided into the reaction chamber in a vapor phase. In an exemplary embodiment, the first metal precursor is an yttrium precursor. For example, the first metal precursor may be Y(EtCp)₂ (iPr-AMD). The first metal precursor is selectively chemisorbed on the first surface relative to the second surface of the substrate. The first metal precursor may be provided into the reaction chamber (i.e. pulsed) for about 0.2 to 10 seconds, for example, about 0.5 seconds, about 1 second, about 3 seconds, about 5 seconds or about 6 seconds. In some embodiments, the first metal precursor is provided into the reaction chamber in multiple, such as 2, 5 or 7, consecutive pulses. In some embodiments, the first metal precursor is provided into the reaction chamber in a single pulse for each deposition cycle. The reaction chamber may be purged after a first metal precursor pulse. Purging is not indicated in FIG. 1, but it may be optionally included in stage 104.

At stage 106, an oxygen precursor is provided into the reaction chamber in a vapor phase. In an exemplary embodiment, the oxygen precursor is water. The oxygen precursor reacts with the chemisorbed first metal precursor or a derivative thereof to form metal oxide on the first surface of the substrate. The reaction chamber may be purged after an oxygen precursor pulse. Purging is not indicated in FIG. 1, but it may be optionally included in stage 106.

The deposition process according to the current disclosure is a cyclic deposition process. Thus, at loop 108, the deposition cycle is initiated again. The deposition cycle may be repeated as many times as needed to deposit a metal oxide layer of desired thickness on the first surface of the substrate. For example, the deposition cycle may be performed from 2 to about 600 times, or from 2 to about 500 times, or from about 5 to about 200 times, or from about 10 to 300 times. For example, the deposition cycle may be performed about 30 times, about 50 times, about 100 times, about 150 times, about 200 times, about 300 times or about 400 times.

The deposition temperature, such as the temperature of the reaction chamber or the substrate support, may be from about 150° C. to about 450° C. or from about 200° C. to about 400° C. For example, the deposition temperature may be about 250° C. or about 300° C. or about 350° C.

Although not detailed in the current disclosure, the process may comprise additional steps, for example refreshing any blocking or passivation that may be necessary for the continued selective deposition, thermal treatments, intermediate etch-back or post-deposition etching. In some embodiments, the selective deposition of a metal oxide layer on the first surface does not damage a passivation, such as an organic passivation layer, for example a polyimide comprising layer, present on the second surface. Further, in some embodiments, metal oxide is substantially not deposited on the passivation. Although not depicted in FIGS. 1 to 4, it is possible for the phases of the deposition process to overlap. For example, phases 104 and 106 may be performed at least partially simultaneously. In some embodiments, phases 104 and 106 are performed at least partially simultaneously.

For example, yttrium oxide layer may be selectively deposited on a first surface of a substrate comprising silicon-containing dielectric material, such as silicon oxide, silicon oxycarbide or silicon nitride relative to a second surface of the same substrate that comprises a metal, such as copper, ruthenium or tungsten. An exemplary deposition temperature may be 300° C., whereas the first metal precursor, Y(EtCp)₂ (iPr-AMD), was kept at a temperature of below 150° C. in a first precursor source vessel. H₂O was used as the oxygen precursor. The yttrium oxide layer growth rate may be, for example between about 0.9 Å/cycle and about 1.5 Å/cycle. Yttrium oxide layers were also deposited using molecular oxygen as the oxygen precursor. A metal oxide layer was obtained, although with a slower growth speed (from about 0.1 Å/cycle to about 1 Å/cycle, depending on the temperature).

Similarly, yttrium oxide could be successfully deposited on HfO₂ surface under similar conditions, the deposition temperature being between 300 and 350° C. Pulse lengths of between 1 second and 3 seconds were found suitable for the yttrium precursor, and 0.25 and 1 seconds for water.

In some embodiments, the metal oxide layer according to the current disclosure has a wet etch rate of 0.1 nm/s or less. By a wet etch rate is herein meant etch rate in 0.5% HF. In some embodiments, the metal oxide layer according to the current disclosure is an yttrium oxide layer, and the yttrium oxide layer has a wet etch rate of 0.005 nm/s or less, such as a wet etch rate of 0.002 nm/s or less, such as about 0.0015 nm/s.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

FIG. 2 is a block diagram of another exemplary embodiment of a method according to the current disclosure. In the method 200 of FIG. 2, blocks 202, 204 and 206 are performed as described of the corresponding blocks 102, 104 and 106 for the embodiment of FIG. 1. In the embodiment of FIG. 2, optional blocking of first surface from passivation 203a, and passivation of the second surface 203b against the deposition of a metal oxide according to the current disclosure are depicted. The optional blocking may be performed, for example, by silylation as described herein, and the passivation by depositing an organic polymer, such as polyimide-comprising layer, on the second surface as described above. In some embodiments, only passivation 203b is performed. For example, passivation of the second surface 203b without a preceding blocking 203a may be performed by silylating a silicon-containing dielectric surface.

Loop 208 corresponds to loop 108 of Fig., and indicates that the deposition of metal oxide layer may be performed after initially passivating the second surface against deposition. However, the optional loop 210 indicates, that the passivation, either containing only block 203b, or both 203a and 203b, may be renewed during the selective deposition process.

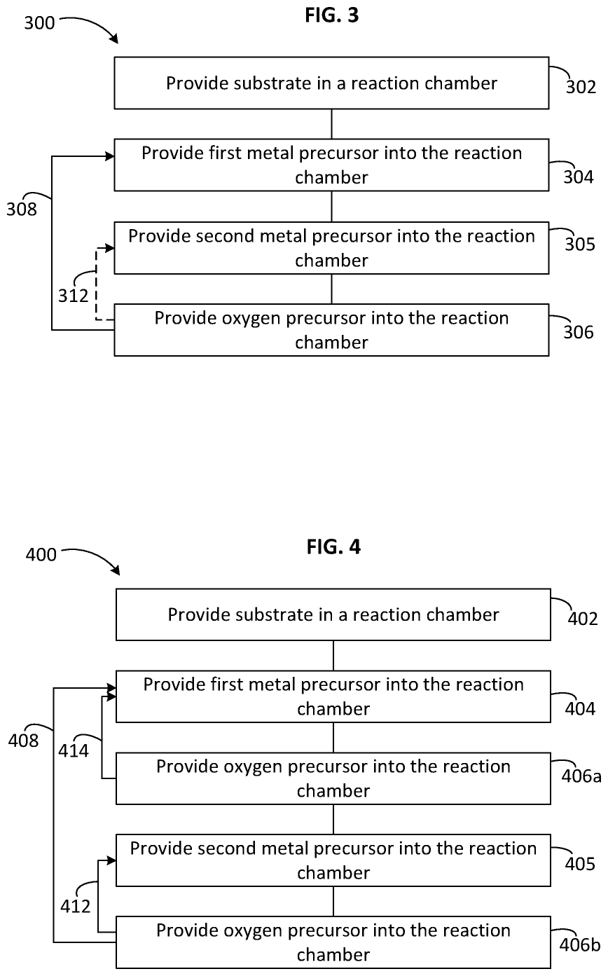

FIG. 3 is a block diagram of a further exemplary embodiment of a method according to the current disclosure. In the embodiments of FIGS. 3 and 4, a second metal precursor is used.

In the method 300 of FIG. 3, blocks 302, 304 and 306 are performed as described of the corresponding blocks 102, 104 and 106 for the embodiment of FIG. 1. However, a second metal precursor may be additionally provided. In this embodiment, both first metal precursor and second metal precursor are provided before an oxygen precursor is provided into the reaction chamber. Although FIG. 3 indicates an embodiment, in which the second metal precursor is provided into the reaction chamber after the first metal precursor, the order of providing the first metal precursor and the second metal precursor into the reaction chamber may be reversed. As indicated by the loops 312 and 308, both of the metal precursors, or only one of them may be provided into the reaction chamber in every deposition cycle.

FIG. 4 is a block diagram of a yet further exemplary embodiment of a method 400 according to the current disclosure. In the embodiment of FIG. 4, a deposition cycle (a master cycle) 408 comprises two subcycles (412 and 414), each of which comprises providing a metal precursor 404, 405, respectively and an oxygen precursor 406a, 406b into the reaction chamber. The method 400 is initiated as described above by providing a substrate in a reaction chamber 402. Then, the deposition is initiated by, for example, providing a first metal precursor into the reaction chamber 404. Although in the embodiment of FIG. 4, the deposition starts with providing the first metal precursor into the reaction chamber, in some embodiments, the deposition may be initiated by providing a second metal precursor or an oxygen precursor into the reaction chamber. In some embodiments comprising a first metal oxide subcycle and second metal oxide subcycle, the relative proportions of the first metal and the second metal in the metal oxide layer, and the layer properties affected by it, can be flexibly regulated.

After the first metal precursor has been provided (e.g., pulsed) into the reaction chamber 404, the reaction chamber may optionally be purged, or an oxygen precursor may be provided into the reaction chamber 406a without purging the reaction chamber. Providing the first metal oxide precursor and the oxygen precursor into the reaction chamber may be termed first metal oxide subcycle. Depending on the desired metal oxide layer composition, the first metal oxide subcycle may be repeated one or more times (loop 414). For example, the first metal oxide subcycle may be performed from 1 to 20 times, such as 1, 2, 3, 5 or 10 times in a master cycle.

After a desired number of first metal oxide subcycles has been performed, a second metal oxide subcycle may be performed one or more times. A second metal oxide subcycle comprises providing a second metal precursor into the reaction chamber 405 and providing an oxygen precursor into the reaction chamber 406b. The oxygen precursor used in the phases 406a and 406b may be the same or a different oxygen precursor, selected from the oxygen precursors described herein. Depending on the desired metal oxide layer composition, the second metal oxide subcycle may be repeated one or more times (loop 412). For example, the second metal oxide subcycle may be performed from 1 to 20 times, such as 1, 2, 3, 5 or 10 times in a master cycle.

After the first metal oxide subcycle and the second metal oxide subcycle have been performed, a master cycle is complete, and it may be repeated, loop 408, and started again. The master cycle may be performed from 1 to about 500 times, such as from 2 to 500 times, or from about 5 to about 500 times, or from about 10 to about 500 times, or from about 20 to about 500 times, or from about 50 to about 500 times, or from about 100 to about 500 times, or from about 250 to about 500 times, or from 2 to about 250 times, or from about 2 to about 150 times, or from about 2 to about 100 times, or from about 2 to about 75 times, or from about 2 to about 50 times, or from about 2 to about 30 times, or from about 2 to about 10 times.

For example, aluminum yttrium oxide may be deposited in variable proportions by the methods according to the current disclosure. The first metal precursor may be Y(EtCp)₂ (iPr-AMD), and the second metal precursor may be dimethylaluminum isopropoxide (DMAI). The first metal oxide subcycle may be performed once for every two, three, four or five second metal oxide subcycles. The composition of a metal oxide layer comprising two different metals according to the current disclosure may have, for example about 27 at-% Al, and about 10 at-% Y, or about 30% Al and about 7.5 at-% Y, or about 31 at-% Al and about 6 at-% Y, or about 30 at-% Al, and about 4.6 at-% Y. The carbon content of the aluminum yttrium oxide layer may be from about 5 at-% to about 13 at-% carbon, with the carbon content increasing with increasing Al content of the layer. The measured leakage current densities of all aluminum yttrium layers were lower than 1E-08 A/cm² at target E fields. Such layers may be 100% selective for a silicon-containing first dielectric surface against a metal surface up to about 7.6 nm thickness on the dielectric surface.

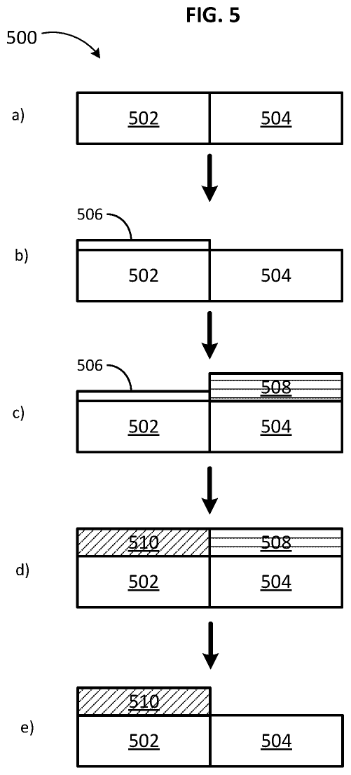

FIG. 5 is a schematic presentation of exemplary embodiments of a method according to the current disclosure. FIG. 5, panels a) to e) illustrates an embodiment of a method according to the current disclosure schematically. In the drawing, a substrate 500 comprising a first surface 502 and a second surface 504 is depicted. The first surface 502 is blocked relative to the second surface 504 by a blocking layer 506, the second surface 504 is selectively passivated by an organic passivation layer 508 relative to the first surface 502 comprising the blocking layer 506, followed by selective deposition of metal oxide layer 510 on the first surface 502 relative to the passivated second surface 504.

Panel a) illustrates a substrate 500 having two surfaces 502, 504 having different material properties. For example, the first surface 502 may be a dielectric surface. The first surface 502 may comprise, consist essentially of, or consist of silicon oxide-based material or another dielectric material, such as silicon-based material described in this disclosure. The second surface 504 may comprise, consist essentially of, or consist of a metal, such as Cu, W or Mo, or a metallic material, such as TiN as disclosed herein.

Panel b) shows the substrate 500 of panel a) after selective blocking of the first surface 502, such as by silylation. Although depicted in FIG. 5 as a layer, the blocking of the first surface 502 may be very thin. Panel c) shows the substrate 500 of panel b) after selective deposition of an organic passivation layer 508 on the second surface 504, such as by formation of a polyimide-comprising layer. It is emphasized that the phases of panels b) and c) are optional, and not always included in the method according to the current disclosure.

Panel d) shows the substrate 500 of panel c) following selective deposition of the metal oxide layer 510 on the first surface 502 relative to the passivated second surface 504 according to the methods disclosed herein. Any metal oxide 510 deposited on the second surface 504, such as on the polymer passivated metal layer 508, can be removed by a treatment, such as an etch-back process. However, this may be challenging for some materials, due to their high etch resistivity. Therefore, in many embodiments, etch back is not performed, but the selectivity of the process is high enough without it. In other embodiments, the metal oxide layer over the second surface 504 may be removed during subsequent removal of the passivation layer 508. In some embodiments, etching is used as a post-deposition process to clean up the final surfaces, and/or to remove passivation.

Panel e) shows the substrate of panel d) after a post-deposition treatment to remove the passivation layer 508 from the second surface 504, such as by an etch process. In some embodiments, the etch process may comprise exposing the substrate 500 to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch process may comprise exposing the substrate to an etchant comprising oxygen, for example O₃. In some embodiments, the substrate may be exposed to an etchant at a temperature of between about 30° C. and about 500° C., or between about 100° C. and about 400° C., or between about 100° C. and about 300° C. In some embodiments, the etchant may be supplied in one continuous pulse or may be supplied in multiple pulses. The removal of the passivation layer 108 can be used to lift-off any remaining metal oxide layer from over the second surface, either in a complete removal of the passivation layer 108 or in a partial removal of the passivation layer 508 in a cyclical selective deposition and removal.

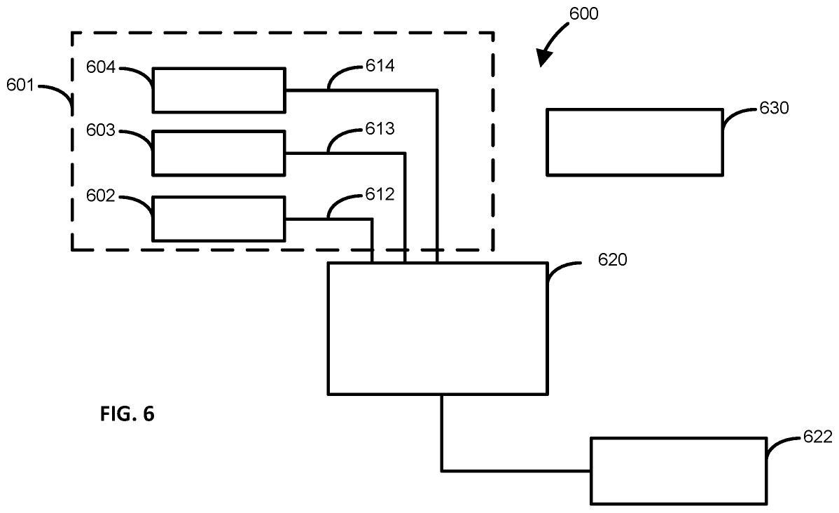

FIG. 6 is a schematic drawing of an embodiment of a semiconductor processing assembly 600 according to the current disclosure.

In yet another aspect, a semiconductor processing assembly 600 for selectively depositing a metal oxide layer on a substrate is disclosed. The semiconductor processing assembly 600 comprises one or more reaction chambers 620 constructed and arranged to hold the substrate, a precursor injector system 601 constructed and arranged to provide a first metal precursor and an oxygen precursor into the reaction chamber in a vapor phase, wherein the semiconductor processing assembly 600 further comprises a first metal precursor source vessel 602 constructed and arranged to contain the first metal precursor and an oxygen source vessel 603 constructed and arranged to contain the oxygen precursor. The semiconductor processing assembly 600 is constructed and arranged to provide the first metal precursor and the oxygen precursor via the precursor injector system 601 into the reaction chamber 620 for selectively depositing metal oxide on the substrate.

In some embodiments, the semiconductor processing assembly 600 further comprises one or more passivation source vessels (not depicted in FIG. 6), and the precursor injector system 601 is constructed and arranged to provide one more passivation agents into the reaction chamber in a vapor phase before providing the first metal precursor into the reaction chamber.

The processing assembly 600 may comprise optional third and further reactant vessels 604 constructed and arranged to contain additional reactants, such as a second metal precursor. The processing assembly 600 may comprise a passivation system for providing the passivation agent—which may comprise one, two or more reactants-into the deposition chamber (not depicted). For example, for a polyimide-comprising passivation layer, two precursors may be used for molecular layer deposition of the passivation material. The third or further reactant vessels may form a part of the passivation system. Thus, in some embodiments, the processing assembly further comprises a passivation system constructed and arranged to provide a passivation agent into a reaction chamber of the processing assembly. The optional third and further reactant vessels 604 may alternatively contain additional reactants used for modifying the deposited material. For example, a third or a further reactant vessel 604 may be constructed and arranged to hold an etchant.

The processing assembly 600 can be used to perform a method as described herein. In the illustrated example, processing assembly 600 includes one or more reaction chambers 620, a precursor injector system 601, a first metal precursor source vessel 602, an oxygen precursor source vessel 603, an optional third (and further) reactant vessel 604, an exhaust source 622, and a controller 630. The processing assembly 600 may comprise one or more additional gas sources (not shown), such as an inert gas source, a carrier gas source and/or a purge gas source. In embodiments, in which blocking and/or passivation is performed in the same processing assembly, the processing assembly 600 may comprise the corresponding sources. Reaction chamber 620 can include any suitable reaction chamber, such as an ALD or CVD reaction chamber as described herein.

The first metal precursor vessel 602 can include a vessel and a first metal precursor as described herein—alone or mixed with one or more carrier (e.g., inert) gases. An oxygen precursor source vessel 603 can include a vessel and an oxygen precursor as described herein-alone or mixed with one or more carrier gases. A third reactant vessel 604 can include a further reactant or a precursor as described herein. Thus, although illustrated with three reactant vessels 602-604, a processing assembly 600 can include any suitable number of reactant vessels. Reactant vessels 602-604 can be coupled to reaction chamber 620 via lines 612-614, which can each include flow controllers, valves, heaters, and the like. In some embodiments, each of the first metal precursors in the first metal precursor source vessel 602, the oxygen precursor in the oxygen precursor source vessel 603 and/or the further reactant in the third reactant vessel 604 may be independently heated or kept at ambient temperature. In some embodiments, a source vessel is heated so that a precursor or a reactant reaches a suitable temperature for vaporization.

Exhaust source 622 can include one or more vacuum pumps.

Controller 630 includes electronic circuitry and software to selectively operate valves, manifolds, heaters, pumps and other components included in the processing assembly 600. Such circuitry and components operate to introduce precursors, reactants and other gases from the respective sources. Controller 630 can control timing of gas pulse sequences, temperature of the substrate and/or reaction chamber 620, pressure within the reaction chamber 620, and various other operations to provide proper operation of the processing assembly 600. Controller 630 can include control software to electrically or pneumatically control valves to control flow of precursors, reactants and other gases into and out of the reaction chamber 620. Controller 630 can include modules such as a software or hardware component, which performs certain tasks. The controller according to the current disclosure is programmed to cause the semiconductor processing assembly to execute a process according to the current disclosure.

Other configurations of processing assembly 600 are possible, including different numbers and kinds of precursor and reactant vessels. For example, a reaction chamber 620 may comprise more than one, such as two or four, deposition stations. Such a multi-station configuration may have advantages if, for example, blocking, passivation and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chamber 620. Further, as a schematic representation of a processing assembly 600, many components have been omitted for simplicity of illustration, and such components may include, for example, various valves, manifolds, purifiers, heaters, containers, vents, and/or bypasses.

During operation of processing assembly 600, substrates, such as semiconductor wafers (not illustrated), are transferred from, e.g., a substrate handling system to reaction chamber 620. Once substrate(s) are transferred to reaction chamber 620, one or more gases from gas sources, such as precursors, reactants, carrier gases, and/or purge gases, are introduced into reaction chamber 620.

The example embodiments of the disclosure described above do not limit the scope of the invention, since these embodiments are merely examples of the embodiments of the methods, structures, devices and processing assemblies, which are defined by the appended claims and their legal equivalents. Any equivalent embodiments are intended to be within the scope of this disclosure. Various modifications of the disclosure, in addition to those shown and described herein, such as alternative useful combinations of the elements described, may become apparent to those skilled in the art from the description. Such modifications and embodiments are also intended to fall within the scope of the appended claims.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of selectively depositing a metal oxide layer on a first surface of a semiconductor substrate relative to a second surface of the substrate; the method comprising:
providing the substrate comprising the first surface and the second surface in a reaction chamber; and
depositing the metal oxide layer on the first surface of the substrate by a cyclic vapor deposition process, wherein the cyclic vapor deposition process comprises:
providing a first metal precursor into the reaction chamber in a vapor phase; and
providing an oxygen precursor into the reaction chamber in a vapor phase;
and wherein the first metal precursor is a heteroleptic precursor comprising a group 3 metal, at least one cyclopentadienyl ligand comprising at least one C1 to C5 alkyl substituent, and at least one acetamidinato ligand.

2. The method of claim 1, wherein the first surface is a dielectric surface.

3. The method of claim 2, wherein the dielectric surface comprises silicon.

4. The method of claim 2, wherein the dielectric surface comprises material selected from the group consisting of SiO₂, SiN, SiC, SiOC, SiON, SiOCN, SiGe and combinations thereof.

5. The method of claim 2, wherein the dielectric surface comprises a metal oxide.

6. The method of claim 5, wherein the metal oxide is selected from the group consisting of aluminum oxide, hafnium oxide and zirconium oxide.

7. The method of claim 1, wherein the second surface is a conductive surface.

8. The method of claim 1, wherein the second surface comprises elemental metal.

9. The method of claim 1, wherein the second surface comprises passivation.

10. The method of claim 9, wherein the passivation comprises a passivation layer on the second surface.

11. The method of claim 1, wherein the method further comprises, before providing the first metal precursor into the reaction chamber, treating the first surface with a silylation agent and thereafter depositing an organic polymer on the second surface.

12. The method of claim 1, wherein the metal of the metal oxide is selected from a group consisting of scandium (Sc), yttrium (Y), lanthanum (La), and cerium (Ce).

13. The method of claim 1 wherein the alkyl substituent of the first metal precursor is selected from the group consisting of methyl, ethyl, and linear or branched alkyl groups containing three, four, or five carbon atoms.

14. The method of claim 13, wherein the first metal precursor comprises two ethylcyclopentadienyl ligands.

15. The method of claim 1, wherein the acetamidinato ligand is an alkylacetamidinato ligand.

16. The method of claim 15, wherein the alkylacetamidinato ligand is a dialkylacetamidinato ligand.

17. The method of claim 15, wherein at least one or two alkyl groups of the alkylacetamidinato ligand is selected from the group consisting of methyl, ethyl, n-propyl, isopropyl, n-butyl, tert-butyl, and sec-butyl.

18. The method of claim 16, wherein the first metal precursor is selected from a group consisting of bis(isopropylcyclopentadienyl)(N,N′-diisopropylacetaminidinato)scandium (Sc(iPrCp)2(iPr-AMD)), bis(ethylcyclopentadienyl)(N,N′-diisopropylacetaminidinato)yttrium (Y(EtCp)₂ (iPr-AMD)), bis(isopropylcyclopentadienyl)(N,N′-diisopropylacetaminidinato)lanthanum (La(iPrCp)₂ (iPr-AMD)), and bis(isopropylcyclopentadienyl)(N,N′-diisopropylacetaminidinato)cerium (Ce(iPrCp)₂ (iPr-AMD)).

19. The method of claim 1, wherein the oxygen precursor selected from the group consisting of molecular oxygen, ozone, hydrogen peroxide, and water.

20. The method of claim 19, wherein two different oxygen precursors are used in the deposition process.

21. The method of claim 1, wherein the deposited metal oxide layer has a thickness from about 0.01 nm to about 5 nm.

22. A semiconductor processing assembly for selectively depositing a metal oxide layer on a substrate, the assembly comprising:
one or more reaction chambers constructed and arranged to hold the substrate;
a precursor injector system constructed and arranged to provide a first metal precursor and an oxygen precursor into the reaction chamber in a vapor phase;
a first metal precursor source vessel constructed and arranged to contain the first metal precursor; and
an oxygen source vessel constructed and arranged to contain the oxygen precursor,
wherein the assembly is constructed and arranged to provide the first metal precursor and the oxygen precursor via the precursor injector system into the reaction chamber for selectively depositing metal oxide on the substrate.
